(19) United States
(12) Patent Application Publication
(10) Pub. No.: US 2025/0096213 A1
(43) Pub. Date: Mar. 20, 2025

(54) OPTICAL PACKAGE STRUCTURE

(71) Applicant: Advanced Semiconductor Engineering, Inc., Kaohsiung (TW)

(72) Inventors: Jenchun CHEN, Kaohsiung (TW); Pai-Sheng SHIH, Kaohsiung (TW); Kuan-Fu CHEN, Kaohsiung (TW); Cheng Kai CHANG, Kaohsiung (TW)

(73) Assignee: Advanced Semiconductor Engineering, Inc., Kaohsiung (TW)

(21) Appl. No.: 18/369,108

(22) Filed: Sep. 15, 2023

(51) Int. Cl. H01L 25/16

(52) U.S. Cl. CPC H01L 25/167

(57) ABSTRACT

An optical package structure is provided. The optical package structure includes a carrier, an optical emitter, an optical receiver, an optical barrier, and an insulating structure. The optical emitter and the optical receiver are over the carrier. The optical barrier is over the carrier and between the optical emitter and the optical receiver, wherein the optical barrier defines a cavity. The insulating structure is filled in the cavity, wherein an elevation of a top surface of the insulating structure is lower than an elevation of a top surface of the optical barrier with respect to a surface of the carrier.

### BACKGROUND

### 1. Technical Field

The present disclosure relates generally to an optical package structure.

### 2. Description of the Related Art

Monitoring biologically-relevant information helps determine a wide array of an individual's physiological characteristics. Integrating a monitoring device (such as a sensor) with a wearable device (such as a pair of glasses, an earpiece, and a watch) allows pertinent information to be collected in a continuous and nonintrusive manner, and thus has become increasingly popular.

### SUMMARY

In one or more arrangements, an optical package structure includes a carrier, an optical emitter, an optical receiver, an optical barrier, and an insulating structure. The optical emitter and the optical receiver are over the carrier. The optical barrier is over the carrier and between the optical emitter and the optical receiver, wherein the optical barrier defines a cavity. The insulating structure is filled in the cavity, wherein an elevation of a top surface of the insulating structure is lower than an elevation of a top surface of the optical barrier with respect to a surface of the carrier.

In one or more arrangements, an optical package structure includes a carrier, an optical emitter, an optical receiver, an encapsulant, and an optical blocking structure. The optical emitter and the optical receiver are over the carrier. The encapsulant encapsulates the optical emitter and the optical receiver. The optical blocking structure is embedded in the encapsulant and between the optical emitter and the optical receiver. The encapsulant includes an optical transmitting structure and a degradation layer between the optical transmitting structure (and the optical blocking structure.

In one or more arrangements, an optical package structure includes a carrier, an optical emitter, an optical receiver, an encapsulant, an optical barrier, and a supporting structure. The optical emitter and the optical receiver are over the carrier. The encapsulant encapsulates the optical emitter and the optical receiver. The optical barrier is over the carrier and between the optical emitter and the optical receiver. The supporting structure is embedded in the optical barrier and configured to increase a uniformity of a compressive strength of an upper surface of the optical package structure.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a top view of an optical package structure in accordance with some arrangements of the present disclosure.

FIG. 1B is a cross-section of an optical package structure in accordance with some arrangements of the present disclosure.

FIG. 1C is a cross-section of an optical package structure in accordance with some arrangements of the present disclosure.

FIG. 1D is a cross-section of a portion of an optical package structure in accordance with some arrangements of the present disclosure.

FIG. 1E is a cross-section of a portion of an optical package structure in accordance with some arrangements of the present disclosure.

FIG. 1F is a cross-section of a portion of an optical package structure in accordance with some arrangements of the present disclosure.

FIG. 2A is a top view of an optical package structure in accordance with some arrangements of the present disclosure.

FIG. 2B is a cross-section of an optical package structure in accordance with some arrangements of the present disclosure.

FIG. 3A is a cross-section of an optical package structure in accordance with some arrangements of the present disclosure.

FIG. 3B is a cross-section of an optical package structure in accordance with some arrangements of the present disclosure.

FIG. 3C is a cross-section of an optical package structure in accordance with some arrangements of the present disclosure.

FIG. 4A is a top view of an optical package structure in accordance with some arrangements of the present disclosure.

FIG. 4B is a cross-section of an optical package structure in accordance with some arrangements of the present disclosure.

FIG. 4C is a top view of an optical package structure in accordance with some arrangements of the present disclosure.

FIG. 4D is a cross-section of an optical package structure in accordance with some arrangements of the present disclosure.

FIG. 5A, FIG. 5B, FIG. 5C, FIG. 5D, FIG. 5E, and FIG. 5F illustrate various stages of an exemplary method for manufacturing an optical package structure in accordance with some arrangements of the present disclosure.

Common reference numerals are used throughout the drawings and the detailed description to indicate the same or similar elements.

### DETAILED DESCRIPTION

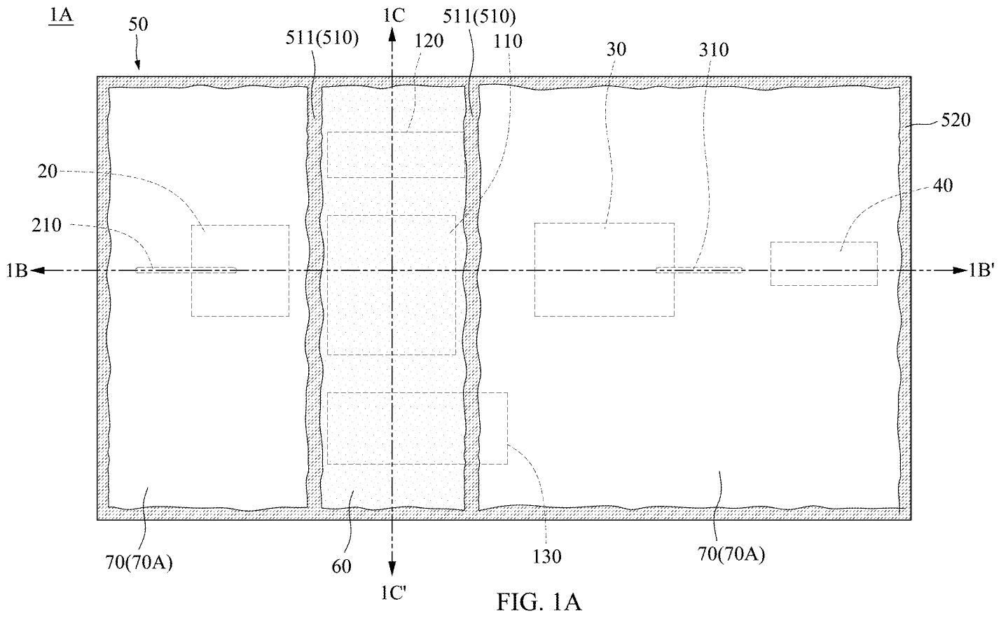

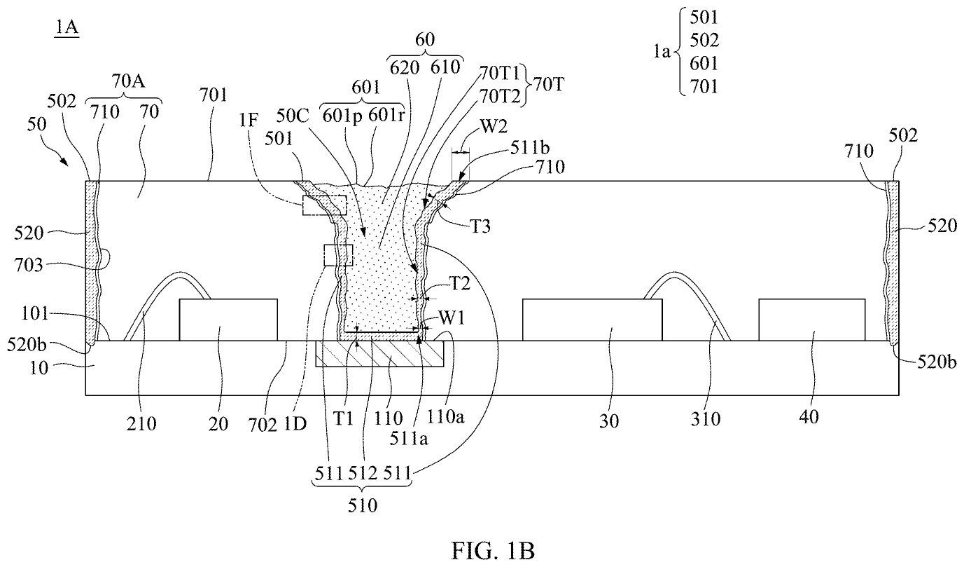

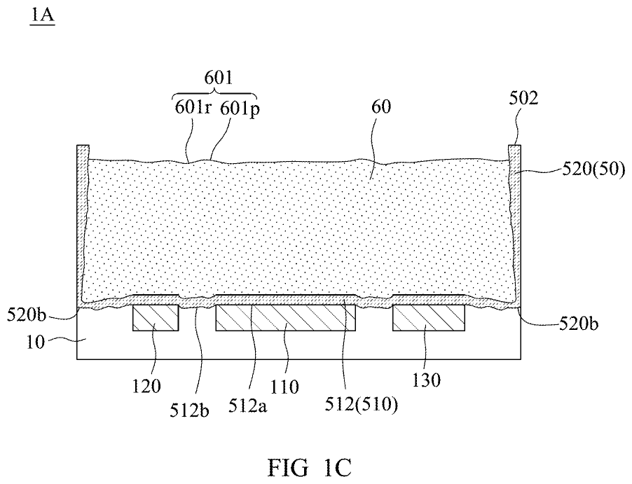

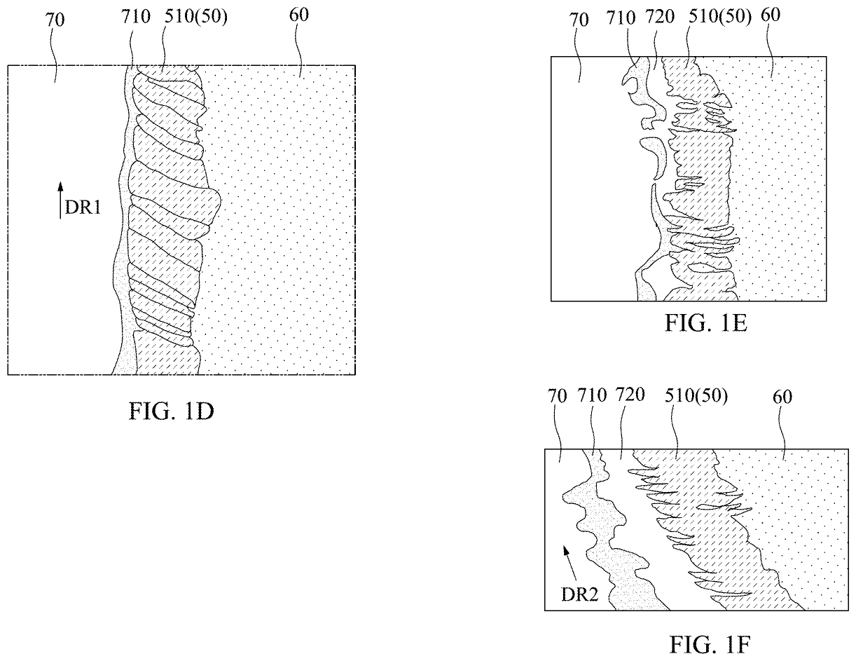

FIG. 1A is a top view of an optical package structure 1A in accordance with some arrangements of the present disclosure. FIG. 1B is a cross-section of an optical package structure 1A in accordance with some arrangements of the present disclosure. FIG. 1C is a cross-section of an optical package structure 1A in accordance with some arrangements of the present disclosure. In some arrangements, FIG. 1B is a cross-section along a cross-sectional line 1B-1B′ in FIG. 1A, and FIG. 1C is a cross-section along a cross-sectional line 1C-1C′ in FIG. 1A.

The optical package structure 1A may include a carrier 10, an optical emitter 20, an optical receiver 30, a device 40, conductive wires 210 and 310, an optical blocking structure, and an encapsulant 70A. The optical package structure 1A may have a top surface 1a (also referred to as “an upper surface”) exposed to a space (e.g. air) outside of the optical package structure 1A. In some arrangements, the top surface 1a includes top surfaces (also referred to as “upper surfaces”) of the encapsulant 70A and one or more top surfaces (also referred to as “upper surfaces”) of the optical blocking structure. The optical package structure 1A may function as a bio-sensor. In some arrangements, the optical package structure 1A may be installed or disposed into a wearable sensor device.

The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, which may include such as a plurality of conductive traces and/or a plurality of conductive vias. The interconnection structure may include a redistribution layer (RDL) and/or a grounding element. In some arrangements, the carrier 10 may include an organic substrate or a leadframe. In some arrangements, the carrier 10 may include a ceramic material or a metal plate. In some arrangements, the carrier 10 may include a two-layer substrate which includes a core layer and a conductive material and/or structure disposed on an upper surface (or a top surface) and a lower surface (or a bottom surface) of the substrate. The carrier 10 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The carrier 10 may include one or more conductive elements, surfaces, contacts, or pads. In some arrangements, the carrier 10 includes conductive pads 110, 120, and 130. Referring to FIG. 1C, the conductive pads 110, 120, and 130 are exposed by a surface 101 of the carrier 10. In some arrangements, the carrier 10 includes a dielectric layer, and the surfaces of the conductive pads 110, 120, and 130 are exposed the dielectric layer. The dielectric layer may have the surface 101. The conductive pad 110 may be connected to ground. In some arrangements, the conductive pads 110, 120, and 130 may independently include a conductive material such as a metal or metal alloy. Examples include gold (Au), silver (Ag), aluminum (Al), copper (Cu), or an alloy thereof. The dielectric layer may include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

The optical emitter 20 (also referred to as “optical emitting device” or “light emitting device”) and the optical receiver 30 (also referred to as “optical receiving device” or “light receiving device”) may be over the carrier 10. The optical emitter 20 may be electrically connected to the carrier 10 through the conductive wire 210. The optical receiver 30 may be electrically connected to the carrier 10 through the conductive wire 310.

The device 40 (also referred to as “electronic component” or “semiconductor device”) may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the device 40 includes a photoelectric conversion component, an electronic control component, or other types of electronic components.

The optical blocking structure may be between the optical emitter 20 and the optical receiver 30. The optical blocking structure is configured to block one or more optical signal from transmitting directly from the optical emitter 20 to the optical receiver 30 without passing any target to be detected. In some arrangements, the optical blocking structure has an optical transmittance (or a light transmittance) of no greater than about 10%, 5%, 3%, or 1%, with respect to a peak wavelength or a range of wavelengths of an optical signal (a light) emitted by the optical emitter 20. In some arrangements, the optical blocking structure may include an optical barrier 50 and a filling structure 60.

In some arrangements, the optical barrier 50 is over the carrier 10. The optical barrier 50 is configured to reflect a light. In some arrangements, the optical barrier 50 includes a material (e.g., a metal material) that is configured to reflect a light. In some arrangements, the optical barrier 50 is at least partially between the optical emitter 20 and the optical receiver 30. In some arrangements, the optical barrier 50 defines a cavity 50C. In some arrangements, a top surface (e.g., top surfaces 501 and 502) of the optical barrier 50 is exposed to a space (e.g. air) outside of the optical package structure 1A. In some arrangements, the optical barrier 50 includes a wall structure. In some arrangements, the optical barrier 50 includes a metal wall structure. The metal wall structure may include a plurality of metal walls. In some arrangements, the optical barrier 50 includes a conductive material such as a metal or metal alloy. Examples include Au, Ag, Al, Cu, an alloy thereof, or stainless steel. In some arrangements, the optical barrier 50 (or the metal wall structure) is electrically connected to the conductive pad 110.

In some arrangements, the optical barrier 50 includes a portion 510 (also referred to as “a first portion”) and a portion 520 (also referred to as “a second portion”). In some arrangements, the portion 510 is between the optical emitter 20 and the optical receiver 30. In some arrangements, the portion 520 is adjacent to one or more outer sidewalls of the encapsulant 70A.

Referring to FIG. 1B, in some arrangements, a thickness of the portion 510 decreases from the top surface 1a toward the carrier 10. In some arrangements, one or more sidewalls of the portion 510 may have an irregular morphology or an irregular profile. In some arrangements, the sidewall of the portion 510 has a plurality of recesses and a plurality of protrusions in a top view perspective. In some arrangements, the sidewall of the portion 510 has a plurality of recesses and a plurality of protrusions in a cross-sectional view perspective. In some arrangements, a maximum distance between bottoms of the recesses and tops of the protrusions is equal to or less than about 1 μm, 0.8 μm, 0.6 μm, 0.4 μm, 0.2 μm, or 0.1 μm.

In some arrangements, the portion 510 includes one or more vertical parts 511 and a horizontal part 512 over the conductive pad 110. A portion of a surface 110a (or a top surface of an upper surface) of the conductive pad 110 may be exposed by the portion 510. In some arrangements, the vertical parts 511 are adjacent to the encapsulant 70A. In some arrangements, the horizontal part 512 contacts the conductive pad 110. In some arrangements, the vertical parts 511 separate the encapsulant 70A into two portions spaced apart from each other. In some arrangements, the vertical parts 511 are connected by the horizontal part 512. In some arrangements, the vertical part 511 includes an end portion 511a connected to the horizontal part 512 and an end portion 511b exposed to a space (e.g. air) outside of the optical package structure 1A. In some arrangements, a thickness T1 of the horizontal part 512 is greater than a width W1 of the end portion 511a and less than a width W2 of the end portion 511b. The thickness T1 may be from about 4 μm to about 7 μm or from about 5 μm to about 6.5 μm. In some arrangements, the vertical part 511 includes a segment (also referred to as “a first segment” or “a lower segment”) connected to the horizontal part 512 and a segment (also referred to as “a second segment” or “an upper segment”) exposed to a space (e.g. air) outside of the optical package structure 1A. The first segment (or the lower segment) may include the end portion 511a, and the second segment (or the upper segment) may include the end portion 511b. In some arrangements, a thickness T3 of the second segment is greater than a thickness T2 of the first segment. The thickness T2 may be from about 1.5 μm to about 5 μm or from about 2 μm to about 4.5 μm. The thickness T3 may be from about 6 um to about 8 um or from about 7 um to about 7.5 um. In some arrangements, the first segment and the second segment of the vertical part 511 extend in different directions. For example, the first segment (or the lower segment) of the vertical part 511 may extend in a direction substantially perpendicular to the surface 101, and the second segment (or the upper segment) of the vertical part 511 may extend in a direction angled with respect to the surface 101. In some arrangements, a roughness (e.g., a surface roughness) of the vertical part 511 is greater than a roughness (e.g., a surface roughness) of the horizontal part 512.

Referring to FIG. 1C, in some arrangements, the horizontal part 512 includes one or more surfaces 512a contacting the conductive pads 110, 120, and 130. In some arrangements, the horizontal part 512 further includes one or more surfaces 512b free from contacting the conductive pads 110, 120, and 130. The surfaces 512b may be recess portions of the surface 101 of the carrier 10. In some arrangements, a roughness (e.g., a surface roughness) of the surface 512a is less than a roughness (e.g., a surface roughness) of the surface 512b. In some arrangements, the portion 520 further has one or more surfaces 520b. The surfaces 520b may be recess portions of the surface 101 of the carrier 10. In some arrangements, a roughness (e.g., a surface roughness) of the surface 512a is less than a roughness (e.g., a surface roughness) of the surface 520b. In some arrangements, the surface 512a is or includes an interface between the horizontal part 512 and the conductive pad 110, 120, and/or 130. In some arrangements, the surface 512b is or includes an interface between the horizontal part 512 and the carrier 10. In some arrangements, the surface 512b is or includes an interface between the horizontal part 512 and the dielectric layer of the carrier 10. In some arrangements, the surface 520b is or includes an interface between the portion 520 and the dielectric layer of the carrier 10. In some arrangements, the horizontal part 512 is conformally formed on a bottom surface of a trench formed by laser cutting that exposes the surfaces of the conductive pads 110, 120, and 130 and the surface of the dielectric layer of the carrier 10. The conductive pads 110, 120, and 130 may serve as laser stoppers for the formation of trenches formed by laser cutting. In some arrangements, the laser cutting operation causes more damages to the dielectric layer of the carrier 10 than to the conductive pads 110, 120, and 130, and thus the surface of the dielectric layer of the carrier 10 subjected to the laser cutting operation is less uniform (e.g., having an irregular surface morphology or having a relatively large roughness) than the surfaces of the conductive pads 110, 120, and 130 subjected to the laser cutting operation. As a result, the roughness of the surface 512a may be less than the roughness of the surface 512b and the roughness of the surface 520b. The surface 512a, the surface 512b, and the surface 520b collectively form a continuous surface contacting the carrier 10.

In some arrangements, the portion 520 surrounds the encapsulant 70A. In some arrangements, the vertical parts 511 of the portion 510 are directly connected to the portion 520. In some arrangements, the optical barrier 50 including the portions 510 and 520 is a single piece element. In some arrangements, the portions 510 and 520 of the optical barrier 50 are formed integrally as a monolithic structure. In some arrangements, the top surface 501 of the portion 510 and the top surface 502 of the portion 520 may be at substantially the same elevation. In some arrangements, one or more sidewalls of the portion 520 may have an irregular morphology or an irregular profile. In some arrangements, the sidewall of the portion 520 has a plurality of recesses and a plurality of protrusions in a top view perspective. In some arrangements, the sidewall of the portion 520 has a plurality of recesses and a plurality of protrusions in a cross-sectional view perspective. In some arrangements, the portion 520 has a substantially planar or flat sidewall exposed to a space (e.g. air) outside of the optical package structure 1A. In some arrangements, a maximum distance between bottoms of the recesses and tops of the protrusions is equal to or less than about 1 μm, 0.8 μm, 0.6 μm, 0.4 μm, 0.2 μm, or 0.1 μm. In some arrangements, a roughness (e.g., a surface roughness) of the surface 110a of the conductive pad 110 is less than a roughness (e.g., a surface roughness) of the surface 520b of the portion 520.

In some arrangements, the filling structure 60 is filled in the cavity 50C. The filling structure 60 is configured to absorb a light. In some arrangements, the filling structure 60 includes a material (e.g., a resin material) that is configured to absorb a light. The filling structure 60 may be or include an insulating structure. The filling structure 60 may be referred to as a supporting element or a supporting structure. In some arrangements, the filling structure 60 is embedded in the optical barrier 50. In some arrangements, the filling structure 60 is embedded in the portion 510 of the optical barrier 50. In some arrangements, the filling structure 60 is surrounded by the optical barrier 50. In some arrangements, the conductive pad 110 directly contacts the optical barrier 50 and is spaced apart from the filling structure 60. In some arrangements, the optical barrier 50 is electrically connected to the conductive pad 110. In some arrangements, the filling structure 60 is configured to increase a uniformity of a compressive strength of or among the top surface 1a of the optical package structure 1A. In some arrangements, an elevation of a top surface 601 (also referred to as “an upper surface”) of the filling structure 60 is lower than an elevation of a top surface (also referred to as “an upper surface”) (e.g., the top surfaces 501 and/or 502) of the optical barrier 50 with respect to the surface 101 of the carrier 10. In some arrangements, the top surface 601 of the filling structure 60 is substantially level with or lower than the top surface (e.g., the top surfaces 501 and/or 502) of the optical barrier 50 with respect to the surface 101 of the carrier 10. In some arrangements, a difference in the elevations of the top surface 601 and the top surface 501 is equal to or less than about 1 μm, 0.8 μm, 0.6 μm, 0.4 μm, 0.2 μm, or 0.1 μm. In some arrangements, the top surface 601 of the filling structure 60 is exposed to a space (e.g. air) outside of the optical package structure 1A. In some arrangements, a roughness (e.g., a surface roughness) of the top surface 601 of the filling structure 60 is greater than a roughness (e.g., a surface roughness) of the top surface (e.g., the top surfaces 501 and/or 502) of the optical barrier 50. In some arrangements, the top surface 601 of the filling structure 60 includes a plurality of recess portions 601r and a plurality of protruding portions 601p. In some arrangements, the filling structure 60 includes a profile tapering from the top surface 601 toward a bottom surface of the insulating structure 60 from a cross-sectional view perspective.

In some arrangements, the filling structure 60 includes a lower portion 610 and an upper portion 620. In some arrangements, a width of the upper portion 620 is greater than a width of the lower portion 610. In some arrangements, the width of the upper portion 620 decreases toward the lower portion 610. In some arrangements, the filling structure 60 may include a dielectric material (or an insulating material) including an organic material, an inorganic material, or a combination thereof. In some arrangements, the filling structure 60 may further include a conductive filler mixed with or dispersed in the dielectric material. In some arrangements, the filling structure 60 is or includes an epoxy resin, a conductive paste (e.g., an Ag paste), a liquid silicone rubber (LSR), a LSR mixed with conductive particles, a LSR mixed with carbon nanotubes, or a combination thereof. In some arrangements, the filling structure 60 may include a material that has a hardness (or a rigidity) greater than or substantially the same as or close to that of the encapsulant 70A. In some arrangements, a modulus of the filling structure 60 is greater than or substantially the same as or close to a modulus of the encapsulant 70A.

In some arrangements, the encapsulant 70A encapsulates at least one of the optical emitter 20, the optical receiver 30, the device 40 and the conductive wires 210 and 310. In some arrangements, the optical blocking structure (e.g., the optical barrier 50 and the filling structure 60) is embedded in the encapsulant 70A and between the optical emitter 20 and the optical receiver 30. In some arrangements, the encapsulant 70A includes an optical transmitting structure 70 and an opaque layer 710, and the opaque layer 71 is between the optical transmitting structure 70 and the optical blocking structure. In some arrangements, the encapsulant 70A is a single piece element. In some arrangements, the optical transmitting structure 70 and the opaque layer 710 are formed integrally as a monolithic structure. In some arrangements, the encapsulant 70A defines a trench 70T, and the optical blocking structure is disposed in the trench 70T. In some arrangements, the optical barrier 50 and the filling structure 60 are disposed in the trench 70T. In some arrangements, the trench 70T extends from the top surface 1a (or the upper surface) toward the surface 101 of the carrier 10. In some arrangements, a width of the trench 70T decreases from the top surface 1a toward the surface 101 of the carrier 10. In some arrangements, the trench 70T includes an upper portion 70T2 and a lower portion 70T1, and a width of the upper portion 70T2 is greater than a width of the lower portion 70T1. In some arrangements, a slope of a sidewall of the upper portion 70T2 with respect to the surface 101 of the carrier 10 is greater than a slope of a sidewall of the lower portion 70T1 with respect to the surface 101 of the carrier 10. In some arrangements, the recess portion (e.g., the surface 512b) of the surface 101 of the carrier 10 and the opaque layer 710 (or the degradation layer) collectively define the trench 70T.

In some arrangements, the optical transmitting structure 70 encapsulates the optical emitter 20, the optical receiver 30, the device 40 and the conductive wires 210 and 310. In some arrangements, a top surface 701 (also referred to as “an upper surface”) of the optical transmitting structure 70 substantially aligns to the top surface (e.g., the top surfaces 501 and/or 502) of the optical barrier 50. In some arrangements, the top surface 701 of the optical transmitting structure 70 is exposed to a space (e.g. air) outside of the optical package structure 1A. n some arrangements, the surface 110a of the conductive pad 110 is not higher than the surface 101 of the carrier 10 and contacting the optical transmitting structure 70. In some arrangements, the top surface 701 of the optical transmitting structure 70 is narrower than a bottom surface 702 of the optical transmitting structure 70. In some arrangements, a roughness (e.g., a surface roughness) of a lateral surface 703 of the optical transmitting structure 70 is greater than a roughness (e.g., a surface roughness) of the top surface 701 of the optical transmitting structure 70. In some arrangements, a roughness (e.g., a surface roughness) of the top surface 601 of the filling structure 60 is greater than a roughness (e.g., a surface roughness) of the top surface 701 of the optical transmitting structure 70. In some arrangements, a roughness (e.g., a surface roughness) of the top surface (e.g., the top surfaces 501 and/or 502) of the optical barrier 50 may be substantially the same as, less than, or greater than a roughness (e.g., a surface roughness) of the top surface 701 of the optical transmitting structure 70. In some arrangements, the portion 520 of the optical barrier 50 surrounds the optical transmitting structure 70. In some arrangements, the optical transmitting structure 70 has an optical transmittance (or a light transmittance) of greater than about 90%, 95%, 97%, or 99%, with respect to a peak wavelength or a range of wavelengths of an optical signal (a light) emitted by the optical emitter 20. In some arrangements, the optical transmitting structure 70 is or includes an epoxy resin, a liquid silicone rubber (LSR), or a combination thereof. In some arrangements, the filling structure 60 and the optical transmitting structure 70 may be formed of or include the same material.

In some arrangements, the opaque layer 710 directly contacts the optical transmitting structure 70. In some arrangements, the opaque layer 710 is spaced apart from the optical emitter 20 and the optical receiver 30 by the optical transmitting structure 70. In some arrangements, the opaque layer 710 extends along at least a portion of the trench 70T. In some arrangements, the opaque layer 710 directly contacts the optical barrier 50 (or the metal wall structure). In some arrangements, the opaque layer 710 directly contacts the portions 510 and 520 of the optical barrier 50 (or the metal wall structure). The opaque layer 710 may be formed by heating a portion of the optical transmitting structure 70. A portion of the optical transmitting structure 70 exposed to the trench 70T may form the opaque layer 710 upon heating (e.g., by the laser cutting operation). In some arrangements, the optical transmitting structure 70 is formed of or includes a polymer layer, and a portion of the polymer layer is degraded or deteriorated upon heating to be transformed into the opaque layer 710. The opaque layer 710 may be referred to as a degradation layer or a deterioration layer. The opaque layer 710 (or the degradation layer or the deterioration layer) formed from a portion of the optical transmitting structure 70 upon heating may change its color (e.g., it may turn darken). The opaque layer 710 and the optical transmitting structure 70 may have different colors. The opaque layer 710 may be a darken portion of the optical transmitting structure 70. In some arrangements, the opaque layer 710 has an optical transmittance (or a light transmittance) lower than that of the optical transmitting structure 70. In some arrangements, the opaque layer 710 has an optical transmittance (or a light transmittance) of less than about 99%, 97%, 95%, 90%, 80%, or 70%, with respect to a peak wavelength or a range of wavelengths of an optical signal (a light) emitted by the optical emitter 20.

The top surface 501 of the optical barrier 50, the top surface 601 of the filling structure 60, and the top surface 701 of the optical transmitting structure 70 collectively form the top surface 1a of the optical package structure 1A. In some arrangements, the top surface 1a may include an optical sensing region (e.g., the top surface 701), a conductive region (e.g., the top surface 501), and a non-conductive region (e.g., the top surface 601) which are distinct from each other and free from overlapping each other. In some arrangements, the optical package structure 1A does not include any protective layer disposed on or covering the top surface 1a. In some arrangements, the optical package structure 1A does not include any optical transmitting protective layer disposed on or covering the top surface 1a.

FIG. 1D is a cross-section of a portion of an optical package structure in accordance with some arrangements of the present disclosure. In some arrangements, FIG. 1D is a cross-section of a portion 1D of the optical package structure 1A in FIG. 1A.

In some arrangements, the portion 510 of the optical barrier 50 includes a multi-layered structure (or a multi-layered wall structure). In some arrangements, the portion 510 includes a plurality of sheet-like microstructures. In some arrangements, the portion 510 includes a plurality of sheet-like grains (or crystal grains) stacked in a direction DR1 substantially perpendicular to the surface 101 of the carrier 10. In some arrangements, the portion 510 has sidewalls with irregular shapes. In some arrangements, an interface between the portion 510 and the filling structure 60 includes a non-planar surface having recessed portions and protruding portions. In some arrangements, an interface between the portion 510 and the opaque layer 710 includes a non-planar surface having recessed portions and protruding portions.

In some arrangements, the opaque layer 710 includes an irregular structure. In some arrangements, an interface between the optical transmitting structure 70 and the opaque layer 710 includes a non-planar surface having recessed portions and protruding portions.

In some arrangements, the portion 520 may have a structure similar to those illustrated in FIG. 1D, and the description is omitted hereinafter.

FIG. 1E is a cross-section of a portion of an optical package structure in accordance with some arrangements of the present disclosure. In some arrangements, FIG. 1E is a cross-section of a portion 1D of the optical package structure 1A in FIG. 1A.

In some arrangements, the optical package structure 1A may further comprising an intermediate layer 720 between the opaque layer 710 and the optical blocking structure (e.g., the optical barrier 50). In some arrangements, the intermediate layer 720 is distinct from the opaque layer 710 and the optical barrier 50. For example, the intermediate layer 720 is or includes a layer or a structure that is distinct or different from the opaque layer 710 and the optical barrier 50 as observed in a SEM image. In some arrangements, the intermediate layer 720 directly contacts the opaque layer 710. In some arrangements, the intermediate layer 720 is directly connected to the optical transmitting structure 70 through an opening of the opaque layer 710. In some arrangements, the intermediate layer 720 directly contacts the optical barrier 50 (or the metal wall structure). In some arrangements, an irregular interface is formed between the intermediate layer 720 and the optical barrier 50 (or the metal wall structure). In some arrangements, the intermediate layer 720 may include a material that is diffused from the optical transmitting structure 70 during manufacture. The intermediate layer 720 may include a conductive material the same as that of the optical barrier 50 and have a structure (e.g., crystal structure) different from that of the optical barrier 50.

In some arrangements, the portion 510 includes a plurality of protrusions and a plurality of recesses. In some arrangements, the protrusions of the portion 510 may extend into the filling structure 60 and/or the intermediate layer 720.

In some arrangements, the opaque layer 710 may include portions spaced apart from each other. In some arrangements, one or more of the portions of the opaque layer 710 may be spaced apart from the portion 510, and another one or more of the portions of the opaque layer 710 may contact the portion 510.

In some arrangements, the portion 520 may have a structure similar to those illustrated in FIG. 1E, and the description is omitted hereinafter.

FIG. 1F is a cross-section of a portion of an optical package structure in accordance with some arrangements of the present disclosure. In some arrangements, FIG. 1F is a cross-section of a portion 1F of the structure in FIG. 1A.

In some arrangements, the portion 510 (or the metal wall) includes an irregular structure extending in a direction DR2 that is angled with respect to the surface 101 of the carrier 10. In some arrangements, the opaque layer 710 includes an irregular structure extending in a direction DR2 that is angled with respect to the surface 101 of the carrier 10. In some arrangements, the intermediate layer 720 includes an irregular structure extending in a direction DR2 that is angled with respect to the surface 101 of the carrier 10.

According to some arrangements of the present disclosure, the optical barrier is between the optical emitter and the optical receiver, and the filling structure is embedded in the optical isolation and having a top surface substantially level with or lower than a top surface of the optical barrier. Therefore, it allows the top surface of the optical blocking structure of the optical package structure to contact and be entirely covered by a target to be detected, crosstalk between the optical emitter and the optical receiver can be effectively prevented, and the optical efficiency can be improved.

In addition, according to some arrangements of the present disclosure, the filling structure is embedded in the optical barrier and has may include a material that has a hardness (or a rigidity) substantially the same as or close to that of the encapsulant. As such, the filling structure can increase the structural strength of the entire semiconductor package structure, and the filling structure can further increase a uniformity of a compressive strength of or among the top surface of the optical package structure. Therefore, the user may be prevented from feeling a foreign body sensation and/or the foreign body sensation can be minimized, and thus discomfort during using the optical package structure as a sensor can be effectively prevented or mitigated. Furthermore, according to some arrangements of the present disclosure, the filling structure filled in the trench of the encapsulant may include a material that has a hardness (or a rigidity) greater than or close to that of the encapsulant. As such, when a foreign body is pressed against the top surface of the optical package structure, the force applied on the top surface may be transferred to the encapsulant to form lateral stress on lateral sides of trench in which the filling structure is formed, and the filling structure having a relatively high hardness (or rigidity) can resist the lateral stress and thus prevent the top surface of the optical package from denting or sinking.

Furthermore, according to some arrangements of the present disclosure, the filling structure is filled in the trench, and the vertical parts of the optical barrier are interposed between the filling structure and the optical transmitting structure. Therefore, the relatively thin vertical parts of the optical barrier can be secured and protected by the filling structure and the optical transmitting structure, and thus cracks and/or damages of the vertical parts of the optical barrier can be prevented.

Moreover, according to some arrangements of the present disclosure, the optical barrier may be electrically connected to ground through the conductive pad of the carrier. Therefore, the optical barrier can provide effects of reduction or prevention of optical crosstalk as well as EMI shielding. Accordingly, the optical sensing performance can be improved, and the electronic performance can be improved as well by shielding electromagnetic interferences.

Furthermore, according to some arrangements of the present disclosure, the trench for disposing the optical blocking structure includes a lower portion and an upper portion wider than the lower portion. As such, the materials of the optical blocking structure may be more easily disposed into the trench. For example, the metal walls of the optical barrier may be more easily disposed on inner sidewalls of the trench by sputtering instead of blocking the opening of the upper portion of the trench by sputtering. That is, an improved step coverage may be achieved. Accordingly, the as-formed optical blocking structure (e.g., the metal wall structure) may define a cavity with a relatively large opening for the filling structure to be disposed therein. Therefore, the filling structure may be filled in the cavity having a relatively dense structure without voids formed therein, and thus the yield as well as the quality of the optical package structure can be improved.

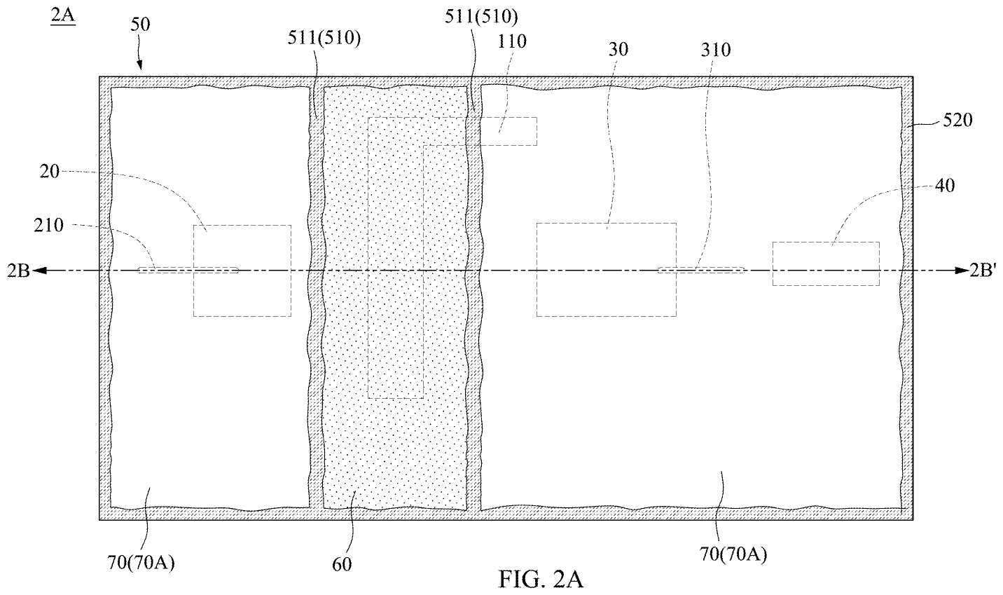

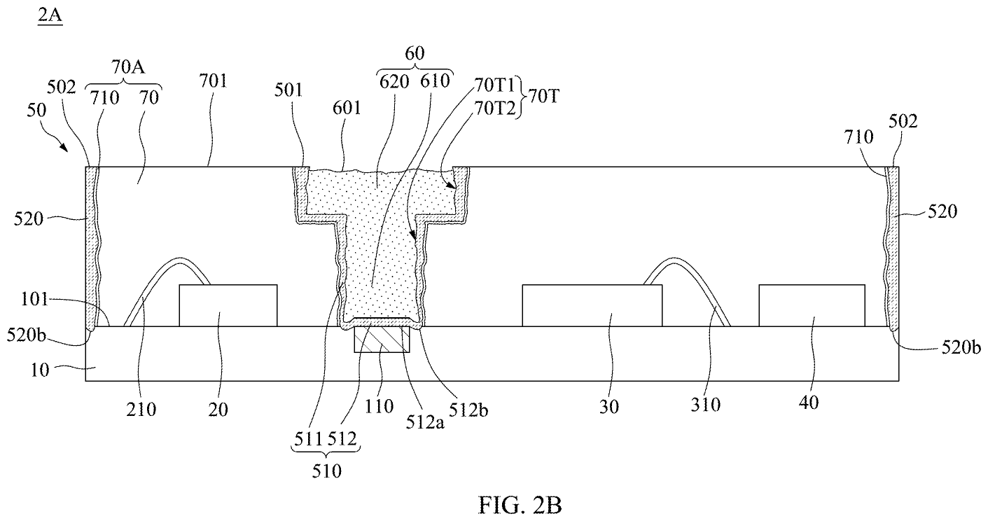

FIG. 2A is a top view of an optical package structure 2A in accordance with some arrangements of the present disclosure. FIG. 2B is a cross-section of an optical package structure 2A in accordance with some arrangements of the present disclosure. In some arrangements, FIG. 2B is a cross-section along a cross-sectional line 2B-2B′ in FIG. 2A. The structure illustrated in FIGS. 2A-2B is similar to that in FIGS. 1A-1C, with differences therebetween as follows.

In some arrangements, the upper portion 70T2 and the lower portion 70T1 of the trench 70T define a stepped profile. In some arrangements, the filling structure 60 includes a stepped structure. In some arrangements, the portion 510 has a stepped profile. In some arrangements, the portion 510 (or the wall structure) of the optical barrier 50 includes a stepped structure. In some arrangements, the opaque layer 710 has a stepped profile.

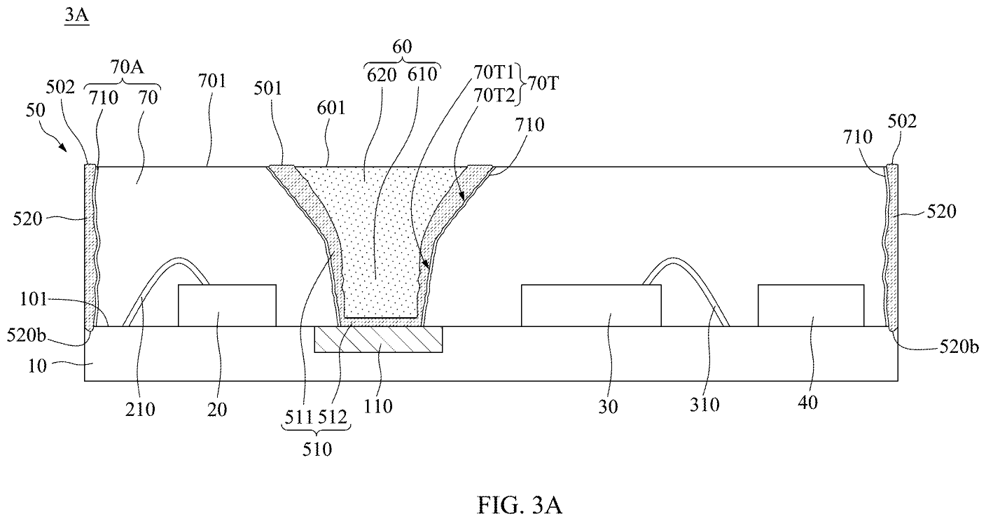

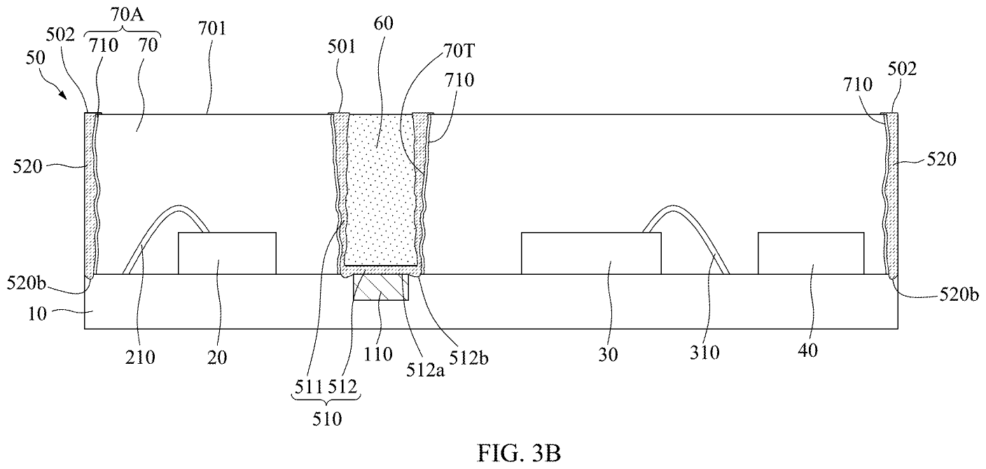

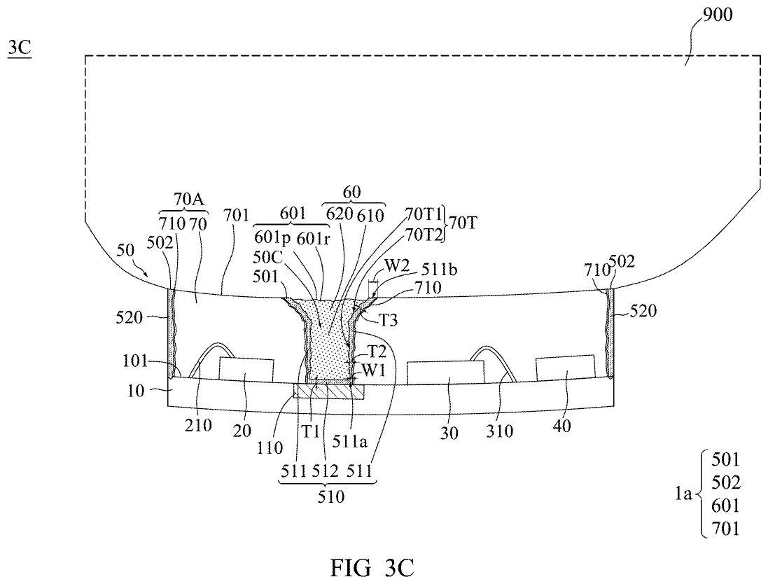

FIG. 3A is a cross-section of an optical package structure 3A in accordance with some arrangements of the present disclosure. The structure illustrated in FIG. 3A is similar to that in FIGS. 1A-1C, with differences therebetween as follows.

In some arrangements, a width of the portion 510 decreases toward the surface 101 of the carrier 10. In some arrangements, the upper portion 70T2 and the lower portion 70T1 of the trench 70T each includes a tapered profile. In some arrangements, a slope of a sidewall of the upper portion 70T2 with respect to the surface 101 of the carrier 10 is greater than a slope of a sidewall of the lower portion 70T1 with respect to the surface 101 of the carrier 10.

In some arrangements, an elevation of the top surface (e.g., the top surfaces 501 and/or 502) of the optical barrier 50 may be higher than an elevation of the top surface 701 of the encapsulant 70A with respect to the surface 101 of the carrier 10. In some arrangements, a difference in the elevations of the top surface 501 and the top surface 701 is equal to or less than about 1 μm, 0.8 μm, 0.6 μm, 0.4 μm, 0.2 μm, or 0.1 μm. In some arrangements, a difference in the elevations of the top surface 502 and the top surface 701 is equal to or less than about 1 μm, 0.8 μm, 0.6 μm, 0.4 μm, 0.2 μm, or 0.1 μm. In some arrangements, an elevation of the top surface 601 of the filling structure 60 may be substantially the same as or lower than that of the top surface 501 of the optical barrier 50 with respect to the surface 101 of the carrier 10. In some arrangements, the elevation of the top surface 601 of the filling structure 60 may be substantially the same as or higher than that of the top surface 701 of the encapsulant 70A with respect to the surface 101 of the carrier 10.

FIG. 3B is a cross-section of an optical package structure 3B in accordance with some arrangements of the present disclosure. The structure illustrated in FIG. 3B is similar to that in FIGS. 1A-1C, with differences therebetween as follows.

In some arrangements, the trench 70T has substantially vertical sidewalls. In some arrangements, an angle defined by the sidewall of the trench 70T and the surface 101 of the carrier 10 is close to 90°, e.g., from 85° to 95°, from 87° to 93°, or from 89° to 91°. In some arrangements, a width of the portion 510 (or the wall structure) of the optical barrier 50 decreases toward the surface 101 of the carrier 10. In some arrangements, the portion 510 may have a substantially planar top surface 501 that covers or overlaps a portion of the top surface 701 of the optical transmitting structure 70. In some arrangements, the filling structure 60 has substantially vertical sidewalls. In some arrangements, the top surface 501 of the optical barrier (or the optical blocking structure) covers a top surface of the opaque layer 710 (or the degradation layer).

FIG. 3C is a cross-section of an optical package structure 3C in accordance with some arrangements of the present disclosure. The structure illustrated in FIG. 3C is similar to that in FIGS. 1A-1C, with differences therebetween as follows.

The optical package structure 3C may be configured to be bent when applied with a pressure from a user. In some arrangements, the top surface la (or the upper surface) of the optical package structure 3C is configured to be or include a curved surface when applied with a pressure from a user. The optical package structure 3C may be configured to measure an electrocardiogram (ECG) signal from a user. In some arrangements, the optical package structure 3C may include an ECG detecting device (e.g., an ECG sensor). In some arrangements, the top surface 501 of the optical barrier 50 is configured to connect to an ECG sensor. During the detection of the ECG signal, a part 900 (e.g., a finger or a portion of a wrist) of a human may contact the top surface 1a and apply pressure on the top surface 1a, such that the top surface 1a may bend to form a concave surface.

In some arrangements, the optical package structure 3C may be bent from an original shape when worn or touched by a finger or a wrist of a human (or a user) and be almost recovered to the original shape after the device including the optical package structure 3C is taken off by the user. In some cases where the optical package structure does not include a filling structure and thus has a relatively low rigidity, the optical barrier may be also bent and recovered accordingly and undergo cyclic stress change, thus fatigue and cracks may occur followingly. According to some arrangements of the present disclosure, the filling structure having a relatively high rigidity is filled in the trench, and the vertical parts of the optical barrier are interposed between the filling structure and the optical transmitting structure. Therefore, the filling structure can provide a rigid structural support for the optical barrier and prevent it from repeatedly being bent and recovered, thus cracks and/or damages of the vertical parts of the optical barrier can be prevented.

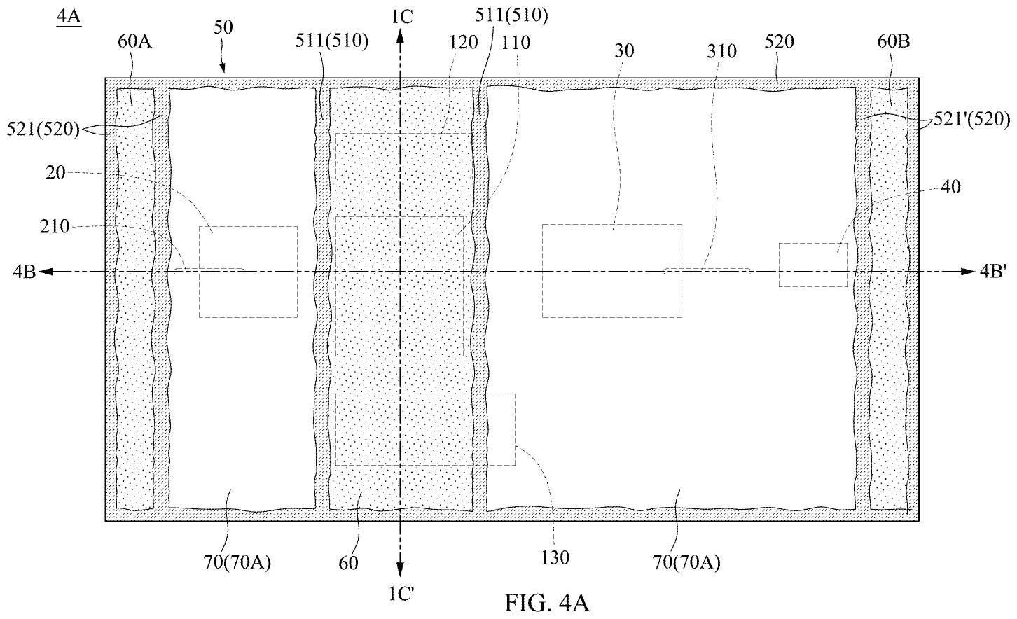

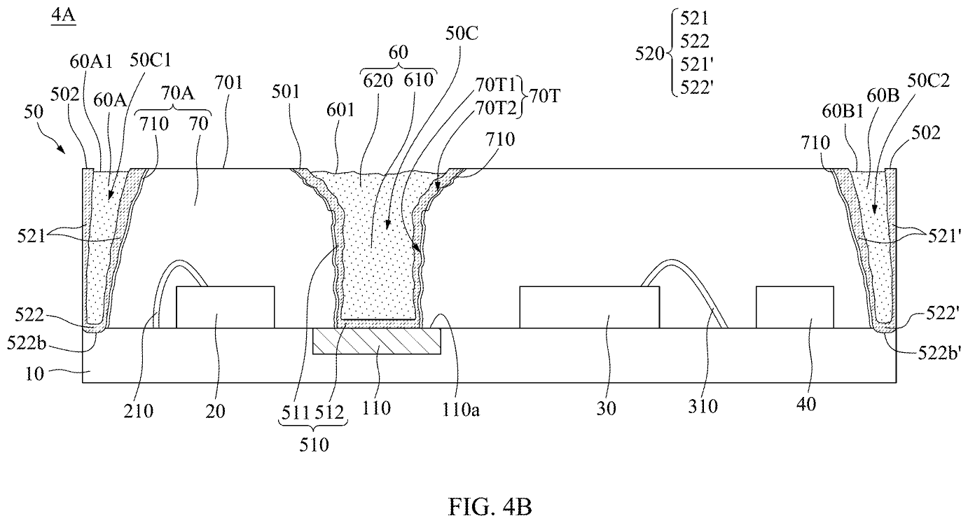

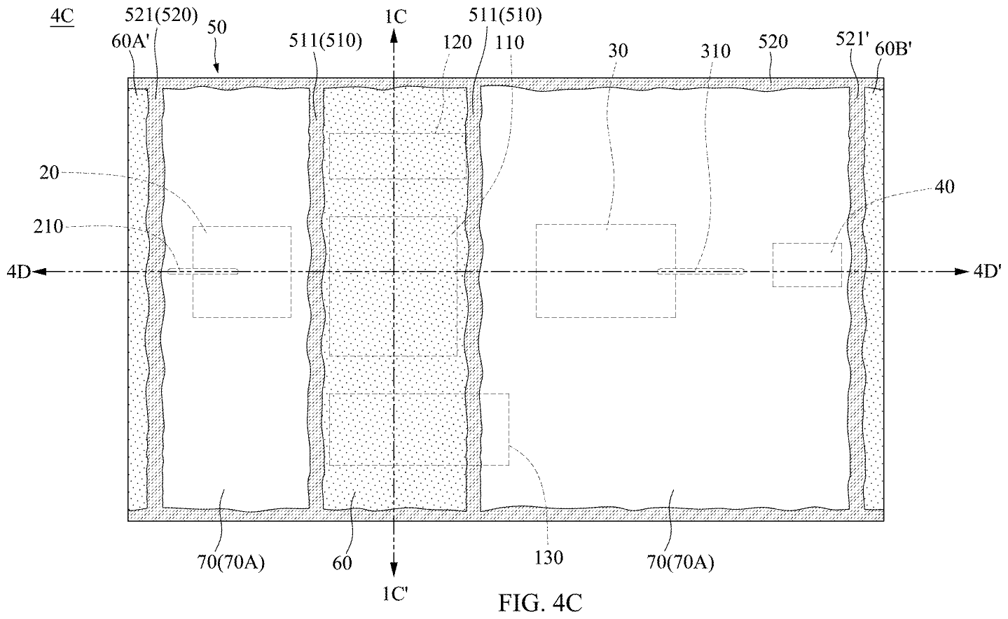

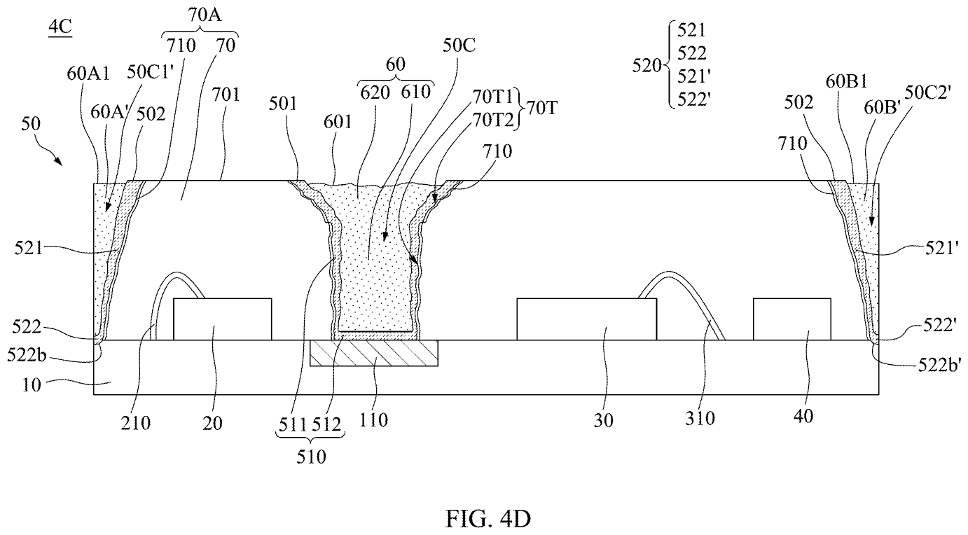

FIG. 4A is a top view of an optical package structure 4A in accordance with some arrangements of the present disclosure. FIG. 4B is a cross-section of an optical package structure 4A in accordance with some arrangements of the present disclosure. In some arrangements, FIG. 4B is a cross-section along a cross-sectional line 4B-4B′ in FIG. 4A. The structure illustrated in FIGS. 4A-4B is similar to that in FIGS. 1A-1C, with differences therebetween as follows.

In some arrangements, the optical package structure 4A may further includes supporting elements 60A and 60B. The supporting elements 60A and 60B may be referred to as filling structures or insulating structure. The supporting elements 60A and 60B may include one or more materials that are the same as that of the filling structure 60 (or the supporting structure). In some arrangements, the supporting elements 60A and 60B are embedded in the portion 520 of the optical barrier 50. In some arrangements, top surfaces 60A1 and 60B1 (also referred to as “upper surfaces”) of the supporting elements 60A and 60B are substantially coplanar with or aligned with the top surface 701 of the encapsulant 70A.

In some arrangements, the portion 520 may further include vertical parts 521 and 521′ and horizontal parts 522 and 522′. In some arrangements, the horizontal parts 522 and 522′ further include surfaces 522b and 522b′ free from contacting the conductive pad 110. The surfaces 522b and 522b′ may be recess portions of the surface 101 of the carrier 10. In some arrangements, a roughness of the surface 522b is greater than a roughness of the surface 110a of the conductive pad 110. In some arrangements, a roughness of the surface 522b is greater than a roughness of an interface between the horizontal part 512 and the conductive pad 110. In some arrangements, a roughness of the surface 522b′ is greater than a roughness of the surface 110a of the conductive pad 110. In some arrangements, a roughness of the surface 522b′ is greater than a roughness of an interface between the horizontal part 512 and the conductive pad 110. In some arrangements, one or more widths of the vertical parts 521 and 521′ may decrease toward the carrier 10. In some arrangements, the horizontal parts 522 and 522′ may each have a thickness greater than one or more thicknesses of one or more lower segments of the vertical parts 521 and 521′. In some arrangements, the vertical parts 521 are connected by the horizontal part 522 to define a cavity 50C1, and the supporting element 60A is disposed in the cavity 50C1. In some arrangements, the supporting element 60A tapers toward the carrier 10. In some arrangements, the vertical parts 521′ are connected by the horizontal part 521′ to define a cavity 50C2, and the supporting element 60B is disposed in the cavity 50C2. In some arrangements, the supporting element 60B tapers toward the carrier 10.

FIG. 4C is a top view of an optical package structure 4C in accordance with some arrangements of the present disclosure. FIG. 4D is a cross-section of an optical package structure 4C in accordance with some arrangements of the present disclosure. In some arrangements, FIG. 4D is a cross-section along a cross-sectional line 4D-4D′ in FIG. 4C. The structure illustrated in FIGS. 4C-4D is similar to that in FIGS. FIGS. 4A-4B, with differences therebetween as follows.

In some arrangements, the optical package structure 4A may further includes supporting elements 60A′ and 60B′. The supporting elements 60A′ and 60B′ may be referred to as filling structures or insulating structure. The supporting elements 60A′ and 60B′ may include one or more materials that are the same as that of the filling structure 60 (or the supporting structure). In some arrangements, top surfaces 60A1 and 60B1 of the supporting elements 60A′ and 60B′ are substantially coplanar with or aligned with the top surface 701 of the encapsulant 70A. In some arrangements, lateral surfaces of the supporting elements 60A′ and 60B′ are exposed to outside of the optical package structure 4C.

In some arrangements, the portion 520 may further include vertical parts 521 and 521′ and horizontal parts 522 and 522′. In some arrangements, the vertical part 521 is connected to the horizontal part 522 to define a cavity 50C1′, and the supporting element 60A′ is disposed in the cavity 50C1′. In some arrangements, the vertical part 521′ is connected to the horizontal part 521′ to define a cavity 50C2′, and the supporting element 60B′ is disposed in the cavity 50C2′. In some arrangements, lateral surfaces of the supporting elements 60A′ and 60B′ are exposed by the vertical parts 521 and 521′. In some arrangements, two sets of the optical emitter 20, the optical receiver 30, and the device 40 may share one supporting element (e.g., the supporting elements 60A and/or 60B illustrated in FIGS. 4A-4B) surrounded by one vertical part of an optical barrier during manufacture, and a singulation operation may be performed on the shared supporting element to form the supporting elements (e.g., the supporting element 60A′ and 60B′) with lateral surfaces exposed, as illustrated in FIGS. 4C-4D.

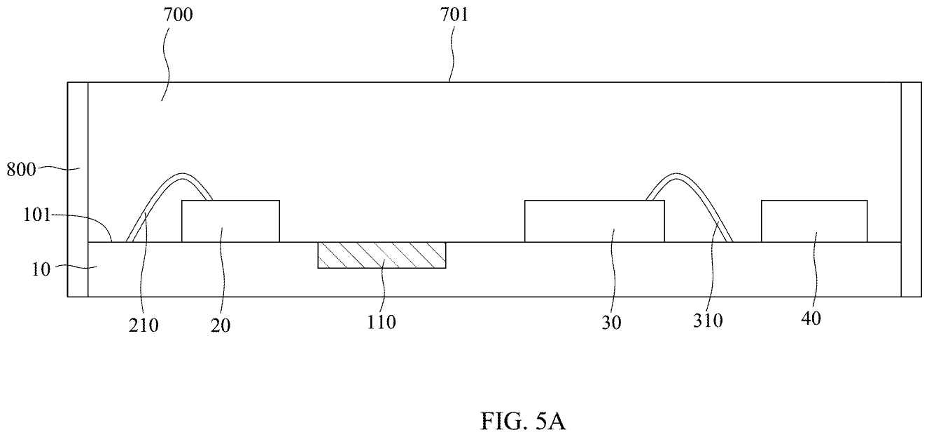

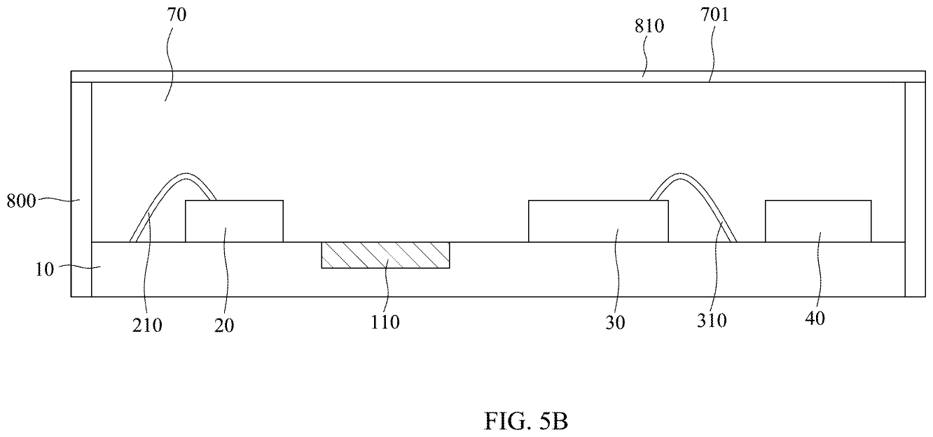

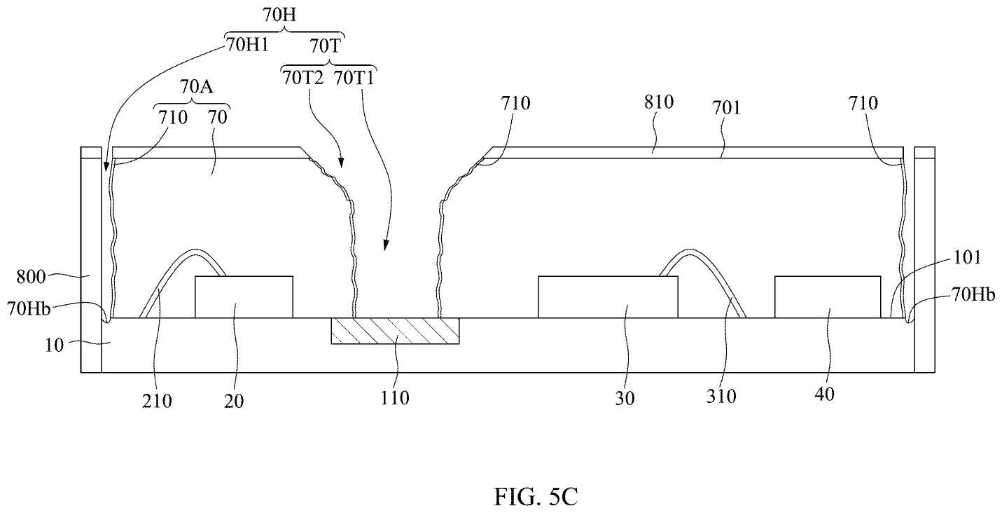

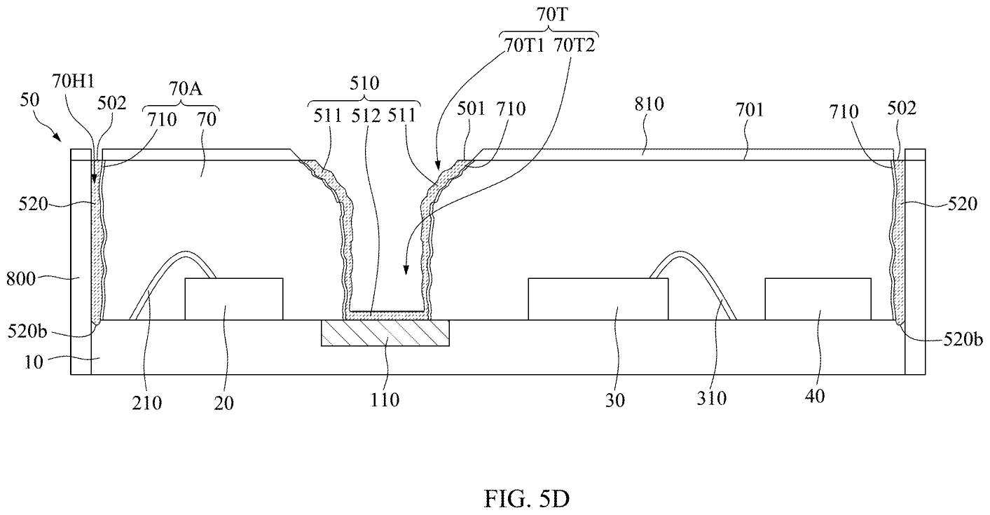

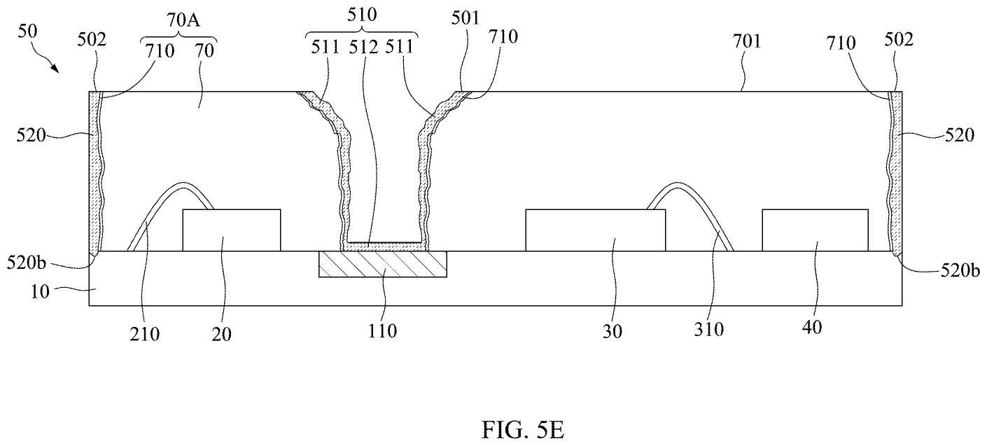

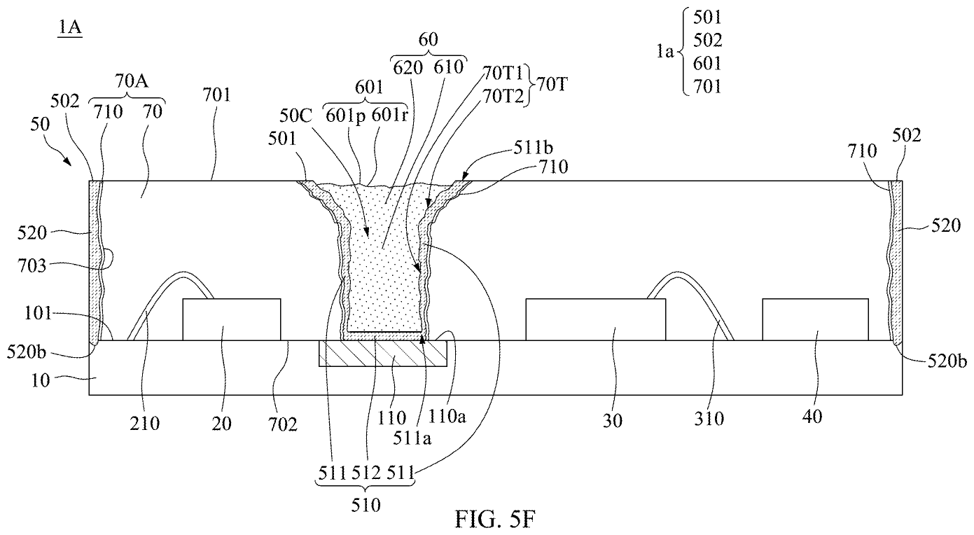

FIG. 5A, FIG. 5B, FIG. 5C, FIG. 5D, FIG. 5E, and FIG. 5F illustrate various stages of an exemplary method for manufacturing an optical package structure 1A in accordance with some arrangements of the present disclosure.

Referring to FIG. 5A, a carrier 10 including one or more conductive pads (e.g., the conductive pad 110) may be provided, an optical emitter 20, an optical receiver 30, and a device 40 may be disposed on the carrier 10. The optical emitter 20 may be electrically connected to the carrier 10 by a conductive wire 210, and the optical receiver 30 may be electrically connected to the carrier 10 by a conductive wire 310. Next, a mold jig 800 may be disposed around the carrier 10. In some arrangements, the mold jig 800 contacts and surrounds the carrier 10. Next, an optical transmitting material 700 may be disposed in a space defined by a surface 101 (or an upper surface) of the carrier 10 and the mold jig 800. The optical transmitting material 700 may be or include a gel. In some arrangements, the optical transmitting material 700 has a relatively high flowability. In some arrangements, the gel-like optical transmitting material 700 is disposed or poured into the space and stays in the space for a predetermined time until a substantially planar top surface 701 of the optical transmitting material 700 is formed, and then a curing operation may be performed on the optical transmitting material 700. In some arrangements, no planarization operation (e.g., a grinding operation or a polishing operation) is performed on the optical transmitting material 700.

Referring to FIG. 5B, after the optical transmitting material 700 is cured to form an optical transmitting structure 70, a heat-resistant sacrificial layer 810 may be disposed to cover the entire top surface 701 of the optical transmitting structure 70. The heat-resistant sacrificial layer 810 may be or include a heat-resistant tape.

Referring to FIG. 5C, a trench structure 70H may be formed within the optical transmitting structure 70. In some arrangements, the trench structure 70H includes trenches 70H1 and 70T. In some arrangements, a trench 70H1 may be formed in a peripheral region of the optical transmitting structure 70. In some arrangements, the trench 70H1 surrounds the optical transmitting structure 70. In some arrangements, inner sidewalls of the mold jig 800 may be exposed to the trench 70H1. The trench 70H1 may have a bottom surface 70Hb extending into a portion of the carrier 10. The bottom surface 70Hb may be recessed from the surface 101. In some arrangements, the trench 70T is between the optical emitter 20 and the optical receiver 30. In some arrangements, the trench 70T includes a lower portion 70T1 and an upper portion 70T2 having a width greater than a width of the lower portion 70T1. In some arrangements, the conductive pad 110 is exposed to the trench 70T. In some arrangements, an opening may be formed within the heat-resistant sacrificial layer 810 that substantially aligns with the top end of the upper portion 70T2 of the trench 70T.

In some arrangements, the trench structure 70H may be formed by a laser cutting operation (also referred to as “laser grooving”). In some arrangements, the trenches 70H1 and 70T are formed by a same laser cutting operation. After the trench structure 70H is formed, an opaque layer 710 may be formed by the heat from the laser cutting operation. In some arrangements, the heat from the laser cutting operation is absorbed by a portion of the optical transmitting structure 70 exposed to the trenches 70H1 and 70T, and the opaque layer 710 is formed along inner sidewalls of the trenches 70H1 and 70T. In some arrangements, the trench 70T may be formed by one or multiple steps of laser cutting operations. For example, a first laser cutting operation may be performed to form a substantially straight trench having substantially vertical sidewalls, and a second layer cutting operation may be performed to widen up an upper portion of the straight trench to form the lower portion 70T1 and the upper portion 70T2 of the trench 70T. The lower portion 70T1 may be formed by the first laser cutting operation, and the upper portion 70T2 may be formed by the second laser cutting operation. The conductive pad 110 may serve as a laser stopper for the formation of the trench 70T. In some arrangements, a portion of carrier 10 (e.g., a dielectric layer of the carrier 10) may be removed by the laser cutting operation to form the trench 70H1 that partially extends into the carrier 10. In some other arrangements, the trench structure 70H may be formed by one or more mechanical cutting operations. In some arrangements, the opening of the heat-resistant sacrificial layer 810 and the trench 70T of the trench structure 70H are formed by a same removal operation. In some arrangements, the opening of the heat-resistant sacrificial layer 810 and the trench 70T of the trench structure 70H are formed by the same laser cutting operation. In some arrangements, the opening of the heat-resistant sacrificial layer 810 and the trench 70T of the trench structure 70H are formed by the same mechanical cutting operations.

According to some arrangements of the present disclosure, the heat-resistant sacrificial layer 810 is formed by the removal operation that forms the trench 70T, such that the opening of the heat-resistant sacrificial layer 810 substantially aligns to the top end of the trench 70T and substantially covers the remained top surface 701 of the optical transmitting structure 70. Therefore, any residues formed from the removal operation (e.g., residues from a laser cutting operation or a mechanical cutting operation) are formed on the heat-resistant sacrificial layer 810 instead of directly contacting or covering the top surface 701 of the optical transmitting structure 70. Accordingly, the top surface 701 of the optical transmitting structure 70 can be prevented from being covered by undesired optical blocking materials.

Referring to FIG. 5D, an optical barrier 50 (or a metal wall structure) may be formed in the trench 70H1 and on inner sidewalls of the trench 70T. In some arrangements, the optical barrier 50 may be formed by sputtering or spray coating. In some arrangements, while the optical barrier 50 is formed by sputtering in a direction DR3 substantially perpendicular to the surface 101 of the carrier 10, the as-formed portion 510 (e.g., vertical parts 511 of the portion 510) of the optical barrier 50 has a width decreasing in the direction DR3. In some arrangements, upper segments of the vertical parts 511 are formed on sidewalls of the upper portion 70T2 of the trench 70T and thus have a relatively large thickness. In some arrangements, lower segments of the vertical parts 511 are formed on sidewalls of the lower portion 70T1 of the trench 70T and thus have a relatively small thickness.

According to some arrangements of the present disclosure, the heat-resistant sacrificial layer 810 covers the top surface 701 of the optical transmitting structure 70 when the optical barrier 50 is formed by sputtering or spray coating. Therefore, the heat-resistant sacrificial layer 810 can prevent the sputtering materials or the coating materials from being directly formed or covering the top surface 701, any sputtering materials or the coating materials that are formed outside of the trench structure 70H can be removed along with the removal of the heat-resistant sacrificial layer 810. Accordingly, the top surface 701 of the optical transmitting structure 70 can be prevented from being covered by undesired optical blocking materials or optical isolation materials.

Referring to FIG. 5E, the mold jig 800 and the heat-resistant sacrificial layer 810 may be removed. In some arrangements, no planarization operation (e.g., a grinding operation or a polishing operation) is performed on the optical barrier 50.

Referring to FIG. 5F, a filling structure 60 may be formed in the cavity 50C within the portion 510 of the optical barrier 50. In some arrangements, the filling structure 60 may be formed by spraying coating, dispensing, printing, or other applicable techniques. In some arrangements, no planarization operation (e.g., a grinding operation or a polishing operation) is performed on the filling structure 60. As such, the optical package structure 1A is formed.

According to some arrangements of the present disclosure, the optical transmitting material has a relatively high flowability, and thus a substantially planar surface of the optical transmitting structure may be formed without any planarization operations (e.g., grinding or polishing).

In addition, according to some arrangements of the present disclosure, the trenches formed by laser cutting operation may have substantially uniform of planar surfaces, and the metal walls of the optical barrier formed on the substantially uniform surface by sputtering may have a relatively dense structure and thereby substantially planar top surfaces. Therefore, the optical barrier and the optical transmitting structure may collectively form a substantially planar top surface of the optical package structure. Accordingly, it allows the planar top surface of the optical package structure to contact and be entirely covered by a target to be detected, crosstalk between the optical emitter and the optical receiver can be effectively prevented, and optical efficiency can be improved.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optical package structure, comprising:
a carrier (10);
an optical emitter (20) and an optical receiver (30) over the carrier (10);
an optical barrier(50) over the carrier (10) and between the optical emitter (20) and the optical receiver (30), wherein the optical barrier (50) defines a cavity (50C); and
an insulating structure (60) filled in the cavity, wherein an elevation of a top surface (601) of the insulating structure (60) is lower than an elevation of a top surface (501) of the optical barrier (50) with respect to a surface (101) of the carrier (10).

2. The optical package structure as claimed in claim 1, wherein the top surface (601) of the insulating structure (60) is exposed to a space outside of the optical package structure (1A).

3. The optical package structure as claimed in claim 1, further comprising an optical transmitting structure (70) encapsulating the optical emitter (20), the optical receiver (30), and the optical barrier (50), wherein a top surface (701) of the optical transmitting structure (70) substantially aligns to the top surface (501) of the optical barrier (50), and the top surface (701) of the optical transmitting structure (70) is narrower than a bottom surface (702) of the optical transmitting structure (70).

4. The optical package structure as claimed in claim 3, wherein the top surface (501) of the optical barrier (50) is configured to connect to an ECG sensor.

5. The optical package structure as claimed in claim 1, further comprising an optical transmitting structure (70) encapsulating at least one of the optical emitter (20) and the optical receiver (30), wherein a roughness of the top surface (601) of the insulating structure (60) is greater than a roughness of the top surface (701) of the optical transmitting structure (70).

6. The optical package structure as claimed in claim 5, wherein a roughness of a lateral surface (703) of the optical transmitting structure (70) is greater than the roughness of the top surface (701) of the optical transmitting structure (70).

7. The optical package structure as claimed in claim 1, wherein the carrier (10) comprises a pad (110) directly contacting the optical barrier (50) and spaced apart from the insulating structure (60).

8. The optical package structure as claimed in claim 7, wherein the optical barrier (50) is electrically connected to the pad (110).

9. The optical package structure as claimed in claim 7, further comprising an optical transmitting structure (70) encapsulating the optical emitter (20), the optical receiver (30), and the optical barrier (50), wherein the pad (110) has an top surface (110a) not higher than the surface (101) of the carrier (10) and contacting the optical transmitting structure (70).

10. The optical package structure as claimed in claim 1, wherein the insulating structure comprises a profile tapering from the top surface toward a bottom surface of the insulating structure from a cross-sectional view perspective.

11. An optical package structure, comprising:
a carrier (10);
an optical emitter (20) and an optical receiver (30) over the carrier (10);
an encapsulant (70A) encapsulating the optical emitter (20) and the optical receiver (30); and
an optical blocking structure (50+60) embedded in the encapsulant (70A) and between the optical emitter (20) and the optical receiver (30),
wherein the encapsulant (70A) comprises an optical transmitting structure (70) and a degradation layer (710) between the optical transmitting structure (70) and the optical blocking structure (50+60).

12. The optical package structure as claimed in claim 11, wherein the degradation layer (710) directly contacts the optical transmitting structure (70).

13. The optical package structure as claimed in claim 11, further comprising an intermediate layer (720) between the degradation layer (710) and the optical blocking structure (50+60), wherein the intermediate layer (720) is distinct from the degradation layer (710).

14. The optical package structure as claimed in claim 13, wherein the intermediate layer (720) is directly connected to the optical transmitting structure (70) through an opening of the degradation layer (710).

15. The optical package structure as claimed in claim 11, wherein the encapsulant (70A) defines a trench (70T), the optical blocking structure (50+60) is disposed in the trench (70T), and the degradation layer (710) extends along at least a portion of the trench (70T).

16. The optical package structure as claimed in claim 15, wherein an upper surface (101) of the carrier (10) has a recess portion (512b), and the recess portion (512b) and the degradation layer (710) collectively define the trench (70T) of the encapsulant (70A).

17. The optical package structure as claimed in claim 15, wherein a top surface (501) of the optical blocking structure (50+60) covers a top surface of the degradation layer (710).

18. An optical package structure, comprising:
a carrier (10);
an optical emitter (20) and an optical receiver (30) over the carrier (10);
an encapsulant (70A) encapsulating the optical emitter (20) and the optical receiver (30);
an optical barrier (50) over the carrier (10) and between the optical emitter (20) and the optical receiver (30); and
a supporting structure (60) embedded in the optical barrier (50) and configured to increase an uniformity of a compressive strength of an upper surface (1a) of the optical package structure.

19. The optical package structure as claimed in claim 18, wherein a rigidity of the supporting structure (60) is greater than a rigidity of the encapsulant (70A).

20. The optical package structure as claimed in claim 18, wherein the optical barrier (50) is configured to reflect a light, and the supporting structure (60) is configured to absorb the light.
